(19) United States
(12) Patent Application Publication
(10) Pub. No.: US 2006/0138430 A1
(43) Pub. Date: Jun. 29, 2006

(54) Heteroisomer boron carbide devices

(76) Inventors: Jennifer I. Brand, Lincoln, NE (US); Anthony N. Caruso, Horace, ND (US); Peter A. Dowhen, Crete, NE (US)

Correspondence Address: SHOOK, HARDY & BACON LLP;INTELLECTUAL PROPERTY DEPARTMENT, 2555 GRAND BLVD, KANSAS CITY,, MO, 64108-2613, US

(21) Appl. No.: 11/195,408

(22) Filed: Aug. 2, 2005

Related U.S. Application Data
(60) Provisional application No. 60/598,142, filed on Aug. 2, 2004.
(60) Provisional application No. 60/604,727, filed on Aug. 26, 2004.

(51) Int. Cl. H01L 31/0312

(52) U.S. Cl. 257/77

(57) ABSTRACT

Semiconductor devices formed using boron carbide heteroisomer junctions or interfaces are provided. The boron carbide heteroisomer junction devices can be incorporated into diodes and transistors.

### CROSS REFERENCE TO RELATED APPLICATIONS

This application claims priority under 35 U.S.C. § 119(e) from Provisional U.S. Patent Application 60/598,142, filed on Aug. 2, 2004, and Provisional U.S. Patent Application 60/604,727, filed on Aug. 24, 2004.

### STATEMENT REGARDING FEDERALLY SPONSORED RESEARCH OR DEVELOPMENT

The Board of Regents of the University of Nebraska acknowledges that some funding for the research leading to this application was provided by the United States Government under Contract/Sponsor/Grant NSF #EPS-9901900 and NSF CHE-0346501.

### TECHNICAL FIELD

This invention is directed to a heteroisomeric semiconductor devices. More particularly, the present invention is directed to diodes and/or transistors constructed using different isomers of the same semiconducting compound, such as boron carbide, to form p-type and n-type regions.

### BACKGROUND OF THE INVENTION

Both p and n type semiconducting materials are a commonly used to form semiconducting devices. A p-n junction diode is a typical example of a device containing such a junction between a p and n type material. A p-n junction diode is a typical example of a device containing such a junction between a p and n type material. The diode can be constructed by forming an interface or junction between a semiconducting material having holes as the majority carrier (the “p” material) and a semiconducting material having electrons as the majority carrier (the “n” material). In addition to single junction devices, multiple junctions can be formed consecutively to form other devices, such as p-n-p or n-p-n transistors. Known semiconducting materials suitable for use in forming p-n junctions include silicon, germanium, gallium arsenide, and boron carbide.

Conventionally, p-n junction devices can be formed as either heterojunction devices or homojunction devices. In heterojunction devices, two semiconductor materials having a different stoichiometry are selected to form a p-n junction. Based on the selection of materials, devices with various bias voltages can be created. Strain can be created at interfaces of dissimilar materials, which can lead to structural defect failure. Different materials may also have diffusion across the interface or side reactions leading to an altogether different semiconductor, which can lead to eventual failure and increased recombination rates for electron-hole pairs.

In homojunction devices, the same bulk semiconductor material is used to form both halves of the p-n junction, but dopants are added to one or both sides of the junction in order to modify the majority carrier. Homojunction devices typically have little or no strain at the junction interface. Due to fabrication difficulties and interdiffusion effects, however, it is difficult to create a sharp transition between the p and n materials. Devices with non-abrupt transitions between the p and n materials typically suffer from increased recombination at the p-n junction. Additionally, doping of the semiconductor materials can lead to introduction of other impurities.

Heterojunction and homojunction devices are useful for a myriad of applications. One area of particular interest is the conversion of the kinetic energy of particles incident upon them to electric energy. This occurs, for example, in photovoltaic cells. A photovoltaic cell typically comprises a plurality of p-n hetero- or homojunction devices designed such that incident photons dislodge electron/hole pairs that may then move in a circuit to form an electric current. While reasonably effective photovoltaics are known, there is a need for devices that can convert other types of incident radiation, such as alpha particles, beta particles, and neutrons, to an electric current.

What is needed are p-n junction devices that are effective for conversion of incident particles into electrical current. The devices should be capable of withstanding a variety of operating environments. The devices should be constructed of materials with a high neutron capture cross-section, and significant capture cross-section for other incident particles of interest as well as stability against radiation damage.

### SUMMARY OF THE INVENTION

The present invention utilizes different isomers of the same semiconducting compound to form p-type and n-type regions. For example, boron carbide, boron carbon phosphide, boron carbon nitride, and boron carbon arsenide are semi-conductors with one or more isomer possessing p-type characteristics and one or more isomer possessing n-type characteristics. Different isomers of such compounds may be used in adjoining regions to form the p-type and n-type regions of diodes or transistors.

### BRIEF DESCRIPTION OF THE DRAWINGS

FIG. 1 schematically depicts a diode according to an embodiment of the invention.

FIG. 2 depicts a process flow for forming heteroisomer junction devices according to an embodiment of the invention.

FIG. 3 schematically depicts ortho boron carbide.

FIG. 4 schematically depicts meta boron carbide.

FIG. 5 schematically depicts para boron carbide.

FIGS. 6a, 6b, and 6c depict various properties of devices according to an embodiment of the invention.

FIG. 7 schematically depicts a transistor in accordance with an embodiment of the invention.

FIG. 8 schematically depicts a transistor in accordance with an embodiment of the invention.

### DETAILED DESCRIPTION OF THE EMBODIMENTS

I. Heteroisomer Junctions of Semiconductor Materials

The present invention provides devices containing heteroisomeric junctions or interfaces of semiconductor materials. A heteroisomeric junction can be created by forming an interface between two semiconductor materials having the same stoichiometry but a different atomic arrangement.

One example of a semiconductor device in accordance with the present invention is a boron carbide diode formed from two boron carbide isomers that have the same stoichiometry and lattice structure but a different atomic arrangement. Because the two boron carbide structures have the same stoichiometry and lattice structure, there is little or no strain at the diode interface. However, the different atomic arrangement of the two boron carbide isomers results in differing electronic properties. This allows a p-n junction to be formed without having to incorporate dopants or other impurities into the boron carbide structures.

In an embodiment, the invention provides semiconducting devices having at least one heteroisomer junction or interface, such as diodes and transistors. In another embodiment, the invention provides methods for fabricating heteroisomer junction devices.

II. Fabrication of Boron Carbide Heteroisomer Junctions

A. Semiconductor and Substrate Materials

A boron carbide heteroisomer diode can be constructed by using two carborane isomers having the chemical composition C₂B₁₀H₁₂ as precursors. In diodes formed according to embodiments of this invention, orthocarborane, or closo-1, 2-dicarbadodecaborane, can be used as a precursor to form a p-type material. Metacarborane, or closo-1, 7-dicarbadodecaborane, can be used as a precursor to form an n-type material.

In another embodiment, other materials may be used to construct a boron carbide diode. Paracarborane, or closo-1, 2-dicarbadodecaborane, can be used as a precursor to form an n-type material in a boron carbide diode. Phospha-carbadodecaborane can be used as a precursor to form a p-type material in a boron carbide diode.

In an embodiment, boron carbide heteroisomer devices can be formed by depositing two or more boron carbide isomer layers on a substrate. One technique for depositing a boron carbide film on a metal substrate is plasma-enhanced chemical vapor deposition (PECVD). In PECVD, the precursor molecule or molecules for forming a desired film, as well as one or more optional inert atoms or molecules, are exposed to an energy source (such as microwave energy) to form a plasma. In an embodiment, the plasma used for depositing a layer of a boron carbide diode is formed using a single precursor, such as orthocarborane or metacarborane. In addition to the precursors, the gas used to form the plasma can also contain one or more inert gases, such as argon.

B. Forming a Boron Carbide Device

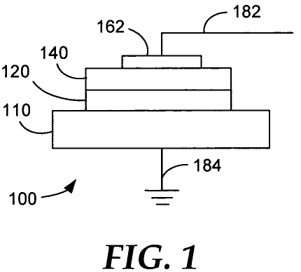

FIG. 1 schematically shows an example of a boron carbide diode according to an embodiment of the invention. In FIG. 1, a diode 100 is formed on a metal substrate 110. A p-type layer 120 is formed on the surface of substrate 110. An n-type layer 130 resides on top of p-type layer 120. An electrical contact 140 is attached to n-type layer 130, to allow the diode to be electrically connected within a device. In the embodiment shown in FIG. 1, substrate 110 is shown connected to ground 184, while electrical contact 140 is shown connected to connecting line 182. This represents a configuration suitable for testing the properties of the diode. Alternatively, the connection to ground 184 can be replaced with another connecting line 182, to allow the diode to be a part of a circuit. Note that in an alternative embodiment, the position of p-type layer 120 and n-type layer 130 can be reversed, so that n-type layer 130 is adjacent to the substrate. In such an embodiment, electrical contact 140 is attached to p-type layer 120.

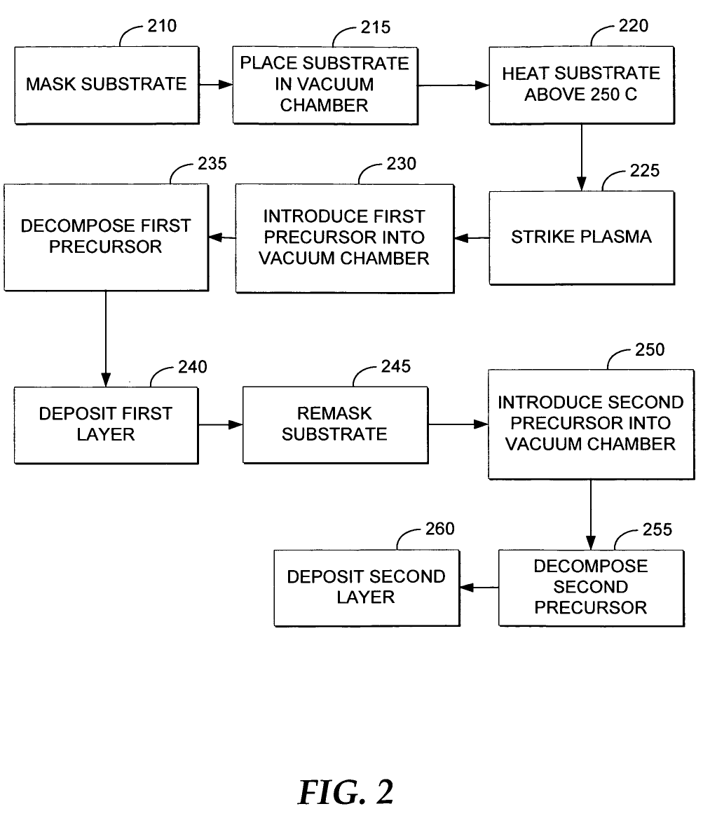

In an embodiment, a PECVD technique can be used to form a boron carbide heteroisomer junction device. FIG. 2 shows a method for forming a heteroisomer junction diode according to an embodiment of the invention. In describing the process shown in FIG. 2, the formation of a p-n junction diode on a metal substrate will be used as an example, with the p-type layer residing on the substrate and the n-type layer residing on top of the p-type layer. However, similar techniques can be used to construct a diode where the n-type layer resides on the substrate, and the p-type layer resides on the n-type layer.

In the embodiment shown in FIG. 2, the method 200 begins by masking 210 a substrate that the diode will be formed on. One skilled in the art will appreciate that the step of masking 210 may use different techniques and may even be omitted entirely, dependent upon the particular needs and objectives of the user. Any convenient material can be used as the substrate. In a preferred embodiment, the substrate is composed of aluminum, nickel, gold, silver, copper, or cobalt substrate, although any other substrate may be used. The masked and appropriately clean substrate is then placed in a vacuum chamber 215. After placing the substrate in the vacuum chamber, the substrate may be heated 220 prior to deposition. Preferably, the substrate is heated to a temperature of 250° C. or higher, although heating 220 is optional.

A plasma, such as argon, is struck 225 in the PECVD chamber. The first precursor is introduced 230 into the chamber. The first precursor decomposes 235 in reaction to the plasma and is deposited 240 as decomposed as the first layer on the substrate. One skilled in the art will appreciate that the thickness of the layer deposited may be controlled by controlling the amount of the first precursor introduced into the chamber. To form p-n junction with the p-material residing on the substrate, orthocarborane can be selected as the first precursor. However, the metacarborane or paracarborane could be used as the first precursor so that an n-type layer is deposited on the substrate.

After forming the first layer on the substrate, a second layer is formed on top of the first layer. In an example where the first layer was a p-type layer formed using orthocarborane as a precursor, the second layer can be formed using a precursor suitable for forming an n-type layer, such as metacarborane or paracarborane. To deposit the second layer, the substrate may be remasked 245, if desired. A second precursor is introduced 250 into the processing chamber. The second precursor decomposes 255 in reaction to the plasma and is deposited 260 as decomposed on the first layer to form a second layer. One skilled in the art will appreciate that the thickness of the second layer may be controlled by controlling the amount of the second precursor introduced into the chamber. The second layer differs from the first layer in the physical configuration of its molecules, rather than the chemical formulation. After forming the second layer, the device may be returned to ambient temperature 270 and removed from the PECVD chamber.

While method 200 is directed to the use of PECVD, one skilled in the art will appreciate that other semiconductor fabrications techniques may be used. For example, the precursors may be deposited and the decomposed, for example using radiation, such as x-rays or electrons. After forming a heteroisomer junction device, one or more electrical connections, such as bonding pads, can be attached to the exposed surfaces of the semiconductor layers. One skilled in the art will appreciate that all or part of method 200 may be repeated to form other devices, such as transistors, by depositing additional layers of isomers. Likewise, further semiconductor techniques may be used before, during, or after method 200 to fabricate other circuit components for use in conjunction with the heteroisomeric device(s) created using method 200. The bonding pad can be composed of the same material as the substrate, or another suitable conductive material. The bonding pad allows a heteroisomer junction device to be electrically connected as a component in a electric circuit. In an embodiment where the heteroisomer junction device is a transistor, the electrical connection can be in either the form of a bonding pad (for the source or drain) or a gate bonding pad (for the gate of the transistor). In another embodiment, a heteroisomer junction device deposited on a conducting substrate can use the substrate for forming electrical connections.

C. Composition of Boron Carbide Layers

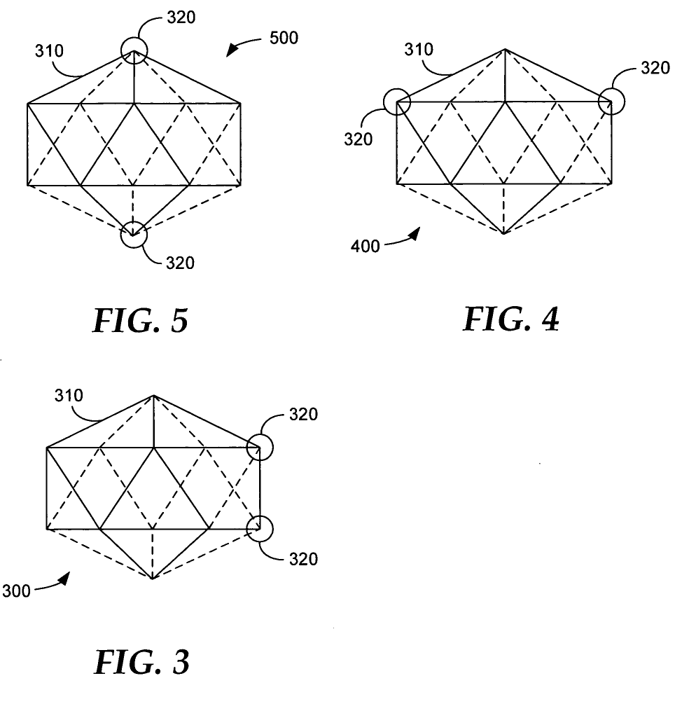

Method 200 shown in FIG. 2 is one way to produce heteroisomer junction devices. FIGS. 3 to 5 show the cage structures corresponding to the ortho, meta, and para isomers of boron carbide. As shown in FIG. 3, the carbons 320 in orthocarborane 300 are at adjacent atomic locations in the cage. FIG. 4 shows the location of carbons 320 in metacarborane 400, while FIG. 5 shows that the carbons 320 are located at the opposite sides of paracarborane 500.

Note that FIGS. 3 to 5 show only bonds 310 between boron and carbon atoms in the cage structure. In the precursor molecules, additional hydrogens would be attached to the cage to form a stable molecule. Boron carbide as illustrated in FIGS. 3 to 5 may exist stably in thin films, such as may be used to form semiconductor devices. In the semiconducting layers used in embodiments of this invention, the cage structures represent repeating units that are found in the boron carbide layers. However, the cage structures within a layer may be deformed to some degree due in order to form a layer.

III. Electrical and Photosensitive Properties of Boron Carbide Diodes

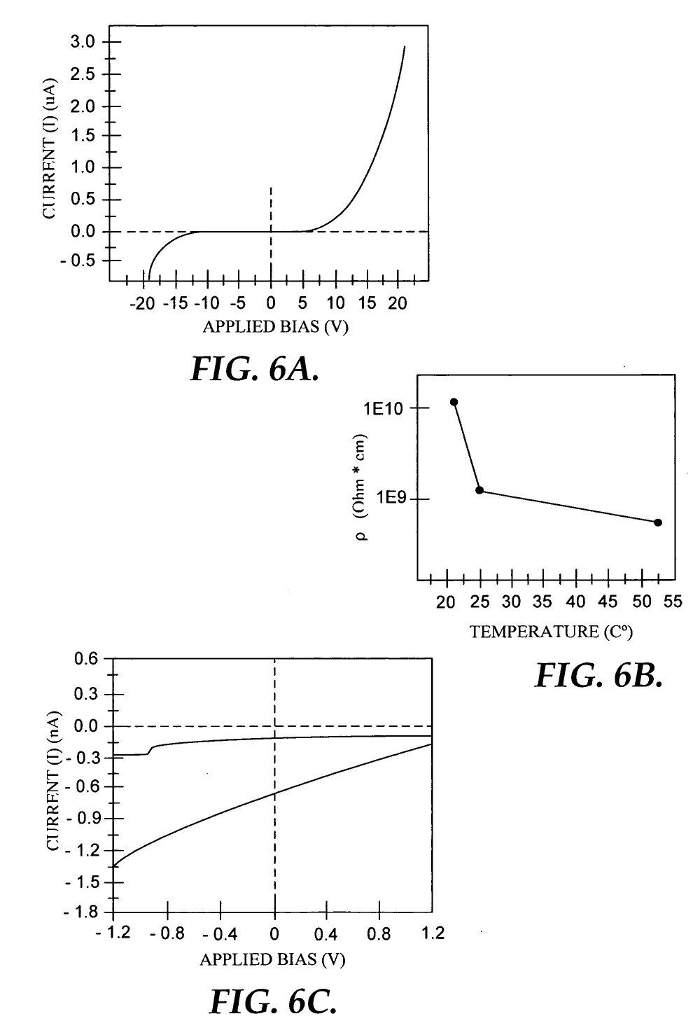

The boron carbide diodes according to various embodiments of the invention have a variety of beneficial properties. FIG. 6a depicts a current versus bias curve for a diode having the configuration shown in FIG. 1, where the substrate is aluminum. As shown in FIG. 6a, the diode used in this example is highly resistive, as indicated by the hysteresis in the diode characteristics. The diode also exhibits only small leakage currents, as shown by the broad plateau near 0 total current for a bias voltages between −5 V and 5 V. The high resistivity of the diode in this example is also shown in FIG. 6b, which depicts the resistivity of the diode as a function of temperature under a reverse bias of 1 V.

FIG. 6c shows the behavior of the same example diode when in the presence of light. In FIG. 6c, the lower line shows the saturation behavior of the diode when exposed to a light source of sufficient intensity. The upper line shows the recovery of the diode after the diode is no longer exposed to the saturating light.

IV. Additional Boron Carbide Device Structures

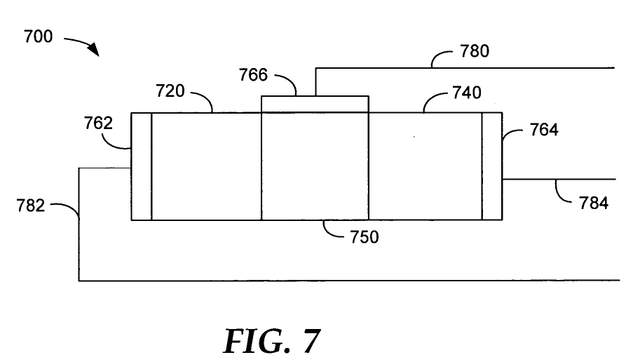

In additional embodiments of the invention, a variety of heteroisomer junction devices can be constructed using heteroisomer p-n junctions. In addition to diodes, transistors can also be constructed, such as p-n-p or n-p-n transistors. FIG. 7 shows an example of a p-n-p or n-p-n transistor structure 700. In an embodiment, a transistor according to the invention can be formed by creating an interface by joining a first isomer material 720, a second isomer material 750, and a third isomer material 740. In such an embodiment, the second isomer material 750 serves as the gate. A gate connection layer 766 or bonding pad is provided to allow electrical connection 780 with a circuit that will provide a gate voltage for controlling the transistor. Electrical connection layers 762 and 764 allow electrical connections 782 and 784 to be formed with the source and drain of the transistor.

In the embodiment shown in FIG. 7, bonding pads 762, 764, and 766 are shown as having the same surface area as the area of the corresponding semiconductor surface. In another embodiment, bonding pads can have a smaller surface area than the corresponding semiconductor surface.

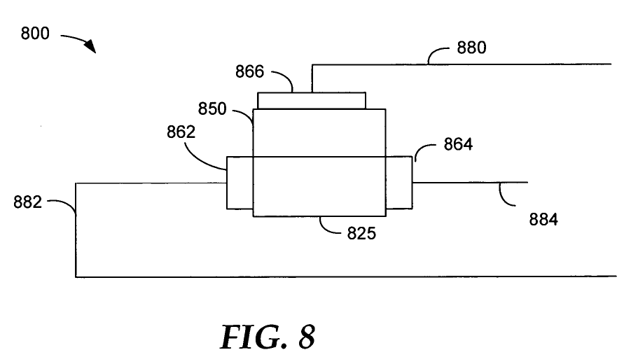

In another embodiment, a transistor can be formed using only a single p-n junction. FIG. 8 shows an example of such an embodiment, where a transistor 800 is formed by creating an interface by joining a first isomer 825 with a second isomer 850. The second isomer material 850 serves as the gate. A gate connection layer 866 or bonding pad is provided to allow electrical connection 880 with a circuit that will provide a gate voltage for controlling the transistor. Electrical connection layers 862 and 864 allow electrical connections 882 and 884 to be formed with two separate surfaces of first isomer 825. In this embodiment, the second isomer layer 850 serves as the gate while the first isomer layer 825 serves as both source and drain.

The principles and modes of operation of this invention have been described above with reference to various exemplary and preferred embodiments. As understood by those of skill in the art, the overall invention, as defined by the claims, encompasses other preferred embodiments not specifically enumerated herein.

What is claimed is:

1. A semiconductor device comprising:
a layer of boron carbide formed by decomposition of orthocarborane; and
a layer of boron carbide formed by decomposition of metacarborane or paracarborane, the layers of boron carbide being joined at an interface.

2. The semiconductor device of claim 1, further comprising a second layer of boron carbide formed by decomposition of orthocarborane, the second layer being joined at a second interface with the layer of boron carbide formed by decomposition of metacarborane.

3. The semiconductor device of claim 1, further comprising a second layer of boron carbide formed by decomposition of metacarborane, the second layer being joined at a second interface with the layer of boron carbide formed by decomposition of orthocarborane.

4. The semiconductor device of claim 1, further comprising an electrical connection layer formed on a surface of at least one boron carbide layer.

5. The semiconductor device of claim 4, wherein the electrical connection layer comprises a bonding pad formed on the surface of the at least one boron carbide layer, the surface of the at least on boron carbide layer having a larger surface area than a surface area of the bonding pad.

6. The semiconductor device of claim 1, further comprising a substrate, wherein at least one boron carbide layer is deposited on the substrate.

7. The semiconductor device of claim 1, wherein the substrate comprises a metal substrate, the metal being selected from the group consisting of aluminum, nickel, gold, silver, cobalt, and copper.

8. A semiconductor device, comprising:
a layer composed from a first isomer of boron carbide; and
a layer composed of a second isomer of boron carbide, the layer composed of the second isomer of boron carbide being deposited on the layer composed of the first isomer.

9. The semiconductor device of claim 8 further comprising a substrate, wherein the layer composed of from the first isomer is deposited on the substrate.

10. The semiconductor device of claim 9, wherein the substrate, the metal being selected from the group consisting of aluminum, nickel, gold, silver, cobalt, and copper.

11. The semiconductor device of claim 8, further comprising a third layer composed of the first isomer of the semiconducting material, the third layer being deposited on the layer composed of the second isomer.

12. The semiconducting device of claim 8, further comprising a third layer composed of a third isomer of the semiconducting material, the third layer being deposited on the layer composed of the second isomer

13. The semiconducting device of claim 12 wherein the first isomer is formed by decomposition of metacarborane or paracarborane and the second isomer is formed by decomposition of orthocarborane.

14. The semiconducting device of claim 8, wherein the layer from the first isomer of the semiconducting material is a p-type material and the layer from the second isomer is an n-type material.

15. The semiconducting device of claim 8, wherein the layer from the first isomer of the semiconducting material is an n-type material and the layer from the second isomer is a p-type material.

16. The semiconducting device of claim 8, wherein the layer of the first isomer is formed by decomposition of orthocarborane, metacarborane, or paracarborane.

17. The semiconductor device of claim 8, further comprising:
an electrical connection layer formed on a surface of the layer composed of the first isomer;
a second electrical connection layer formed on a second surface of the layer composed of the first isomer; and
a gate connection layer formed on a surface of the layer composed of the second isomer.

18. A boron carbide diode, comprising:
a p-type semiconducting layer formed from an orthocarborane precursor; and
an n-type semiconducting layer formed from a precursor selected from the group consisting of metacarborane, paracarborane, other substituted carboranes atoms such as some phosphocarborane isomers,

19. A semiconductor device, comprising:
a layer composed of a first isomer of a semiconducting material deposited on a substrate;
a second layer composed of a second isomer of the semiconducting material, the layer composed of the second isomer being deposited on the layer composed of the first isomer;
a third layer composed of the first isomer of the semiconducting material, the third layer being deposited on the second layer;
an electrical connection layer formed on a surface of at least one layer composed of the first isomer; and
a gate connection layer formed on a surface of the second layer.

20. The semiconductor device of claim 21, further comprising a substrate, wherein at least one of the layers of the semiconducting material is deposited on the substrate

21. The semiconductor device of claim 21, wherein the electrical connection layer comprises a bonding pad and the surface of the at least one layer composed of the first isomer has an area larger than a surface area of the bonding pad.

22. The semiconductor device of claim 21, wherein the gate connection layer comprises a bonding pad, wherein the surface of the second layer has an area larger than a surface area of the bonding pad.
